(19) United States
(12) Patent Application Publication
(10) Pub. No.: US 2025/0167015 A1
(43) Pub. Date: May 22, 2025

(54) APPARATUS FOR MANUFACTURING SEMICONDUCTOR PACKAGE AND METHOD OF MANUFACTURING SEMICONDUCTOR PACKAGE

(71) Applicant: Samsung Electronics Co., Ltd., Suwon-si (KR)

(72) Inventor: Donguk KWON, Suwon-si (KR)

(73) Assignee: Samsung Electronics Co., Ltd., Suwon-si (KR)

(21) Appl. No.: 18/668,361

(22) Filed: May 20, 2024

(30) Foreign Application Priority Data
Nov. 17, 2023 (KR) 10-2023-0159710

(51) Int. Cl. H01L 21/67; H01L 21/60; H01L 21/603; H01L 21/683; H01L 23/00

(52) U.S. Cl. CPC H01L 21/67121; H01L 21/60; H01L 21/603; H01L 21/67103; H01L 21/6838; H01L 24/742; H01L 2021/6003; H01L 2021/60135; H01L 2021/6015; H01L 2224/742; H01L 2224/75272

(57) ABSTRACT

The inventive concept relates to an apparatus for manufacturing a semiconductor package and a method of manufacturing a semiconductor package. According to embodiments, the method of manufacturing a semiconductor package may include preparing a substrate including upper conductive pads on an upper surface of the substrate, preparing a first semiconductor chip including first solder balls, wherein a first dielectric layer covering sidewalls of the first solder balls is on a lower surface of the first semiconductor chip, disposing the first semiconductor chip on the substrate such that the first solder balls are on the upper conductive pads, and bonding the first solder balls to the upper conductive pads by applying an alternating current electric field to the first dielectric layer.

### CROSS-REFERENCE TO RELATED APPLICATION

This application is based on and claims priority under 35 U.S.C. § 119 to Korean Patent Application No. 10-2023-0159710, filed on Nov. 17, 2023, in the Korean Intellectual Property Office, the disclosure of which is incorporated by reference herein in its entirety.

### BACKGROUND

The inventive concepts relate to an apparatus for manufacturing a semiconductor package and methods of manufacturing a semiconductor package by using the apparatus, and more particularly, to a bonding apparatus and a bonding method using the bonding apparatus.

As electronic products have become more high-performance, semiconductor packages including semiconductor chips are used. A semiconductor chip may be electrically connected to a substrate or a plurality of semiconductor chips may be electrically connected to each other through a bonding process. In the bonding process, the semiconductor chip or the substrate may be damaged. For example, warpage of the semiconductor chip may occur. Alternatively, the bonding process takes a relatively long time, causing a decrease in process efficiency.

### SUMMARY

The inventive concepts provide a methods of improving the productivity of a method of manufacturing a semiconductor package, and an apparatus for manufacturing a semiconductor package, which is used in the method.

The inventive concepts provide a bonding apparatus that prevents or reduces in likelihood damage to semiconductor chips.

The inventive concepts may provide an apparatus for manufacturing a semiconductor package and a method of manufacturing a semiconductor package. According to an aspect of the inventive concepts, there may be provided a method of manufacturing a semiconductor package, the method including preparing a substrate including upper conductive pads on an upper surface of the substrate, preparing a first semiconductor chip including first solder balls, wherein a first dielectric layer covering sidewalls of the first solder balls is on a lower surface of the first semiconductor chip, disposing the first semiconductor chip on the substrate such that the first solder balls are on the upper conductive pads, and bonding the first solder balls to the upper conductive pads by applying an alternating current electric field to the first dielectric layer.

According to another aspect of the inventive concepts, there may be provided an apparatus for manufacturing a semiconductor package, the apparatus including a bonding chuck including a first electrode and defining a first adsorption hole, a bonding head including a second electrode and defining a second adsorption hole, and an alternating current power generator electrically connected to the first electrode and the second electrode, wherein the apparatus is configured to apply an alternating current voltage to the first electrode and the second electrode by driving the alternating current power generator, the first adsorption hole penetrates an upper surface of the bonding chuck, and the second adsorption hole penetrates a lower surface of the bonding head.

According to another aspect of the inventive concepts, there may be provided a method of manufacturing a semiconductor package, the method including preparing a bonding apparatus including a bonding chuck, the bonding chuck including a first electrode, a bonding head, the bonding head including a second electrode, and an alternating current power generator electrically connecting the first electrode to the second electrode, disposing a substrate on the bonding chuck, the substrate including upper conductive pads, preparing a semiconductor chip including solder balls, the semiconductor chip including a dielectric layer covering sidewalls of the solder balls, exposing lower surfaces of the solder balls, and the dielectric layer is provided on a lower surface of the semiconductor chip, disposing the semiconductor chip on the substrate by using the bonding head such that the solder balls are provided on the upper conductive pads, and bonding the solder balls to the upper conductive pads by applying an alternating current voltage to the first electrode and the second electrode.

### BRIEF DESCRIPTION OF THE DRAWINGS

Example embodiments of the inventive concepts will be more clearly understood from the following detailed description taken in conjunction with the accompanying drawings in which:

FIG. 1 is a cross-sectional view of an apparatus for manufacturing a semiconductor package according to some example embodiments;

FIG. 2A is a diagram illustrating an apparatus for manufacturing a semiconductor package according to some example embodiments;

FIG. 2B is a diagram illustrating an apparatus for manufacturing a semiconductor package according to some example embodiments;

FIG. 3A is a diagram illustrating an apparatus for manufacturing a semiconductor package according to some example embodiments;

FIG. 3B is a diagram illustrating an apparatus for manufacturing a semiconductor package according to some example embodiments;

FIGS. 4A to 4J are diagrams illustrating a method of manufacturing a semiconductor package, according to some example embodiments;

FIG. 5 is a cross-sectional view of a semiconductor package according to some example embodiments;

FIGS. 6A to 6E are diagrams illustrating a method of manufacturing a semiconductor package, according to some example embodiments; and

FIG. 7 is a cross-sectional view of a semiconductor package according to some example embodiments.

### DETAILED DESCRIPTION OF THE EMBODIMENTS

Herein, like reference numerals denote like elements. Hereinafter, apparatuses for manufacturing semiconductor packages according to some example embodiments and methods of manufacturing semiconductor packages by using the apparatus are described.

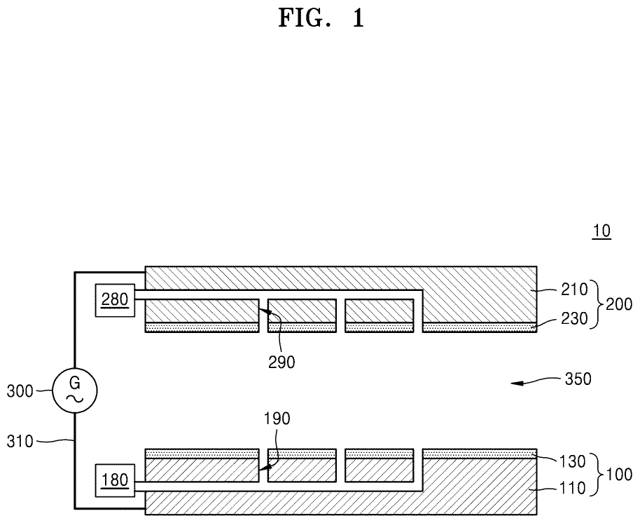

FIG. 1 is a cross-sectional view of an apparatus for manufacturing a semiconductor package according to example embodiments.

Referring to FIG. 1, an apparatus 10 for manufacturing a semiconductor package may be a bonding apparatus. For example, a plurality of semiconductor chips may be bonded to each other or a semiconductor chip may be bonded to a substrate by using the apparatus 10 for manufacturing a semiconductor package. The apparatus 10 for manufacturing a semiconductor package may include a bonding chuck 100, a bonding head 200, and an alternating current power generator 300. The apparatus 10 for manufacturing a semiconductor package may further include a first vacuum pump 180 and a second vacuum pump 280. A bonding space 350 may be provided between the bonding chuck 100 and the bonding head 200.

The bonding chuck 100 may be configured to support a substrate or a semiconductor chip. A substrate or a semiconductor chip may be disposed on an upper surface of the bonding chuck 100. The upper surface of the bonding chuck 100 may be a support surface.

The bonding chuck 100 may include a first electrode 110 and a first insulating layer 130. The first electrode 110 may include a conductive material such as metal. For example, the first electrode 110 may include copper, titanium, tungsten, aluminum, stainless steel (SuS), and/or a combination thereof. The first insulating layer 130 may be provided on an upper surface of the first electrode 110 to cover the upper surface of the first electrode 110. The first insulating layer 130 may prevent or reduce in likelihood a substrate or a semiconductor chip from contacting the first electrode 110. The first insulating layer 130 may include an insulating polymer or an insulating inorganic material. An upper surface of the first insulating layer 130 may correspond to the upper surface of the bonding chuck 100.

The bonding chuck 100 may include a first adsorption hole 190. For example, the bonding chuck 100 may define the first adsorption hole 190. An upper portion of the first adsorption hole 190 may be open toward the bonding space 350. The first adsorption hole 190 may penetrate the upper surface of the bonding chuck 100. The first adsorption hole 190 may be provided in the first electrode 110 and may penetrate the first insulating layer 130. The first electrode 110 may function as an adsorption unit. The first adsorption hole 190 may be connected to the first vacuum pump 180. In a bonding process, vacuum pressure may be applied to the first adsorption hole 190 by the first vacuum pump 180 so that the first adsorption hole 190 may be provided in a vacuum state. The bonding chuck 100 may be configured to fix a substrate or a semiconductor chip by using the vacuum pressure in the first adsorption hole 190. The bonding chuck 100 may include a plurality of first adsorption holes 190. The first vacuum pump 180 may be disposed on one side of the bonding chuck 100. Alternatively, the arrangement of the first vacuum pump 180 may be variously modified. For example, the first vacuum pump 180 may be provided on a lower surface of the bonding chuck 100.

The bonding head 200 may include a second electrode 210 and a second insulating layer 230. The second electrode 210 may include a conductive material such as metal. For example, the second electrode 210 may include copper, titanium, tungsten, aluminum, SuS, and/or a combination thereof. The second insulating layer 230 may be provided on a lower surface of the second electrode 210 to cover the lower surface of the second electrode 210. The second insulating layer 230 may include an insulating polymer or an insulating inorganic material. A lower surface of the second insulating layer 230 may correspond to a lower surface of the bonding head 200. The lower surface of the bonding head 200 may be a contact surface. For example, the lower surface of the bonding head 200 may be configured to contact a semiconductor chip. The bonding head 200 may function as a compressor. For example, the bonding head 200 may apply pressure to a semiconductor chip.

The bonding head 200 may include a second adsorption hole 290. For example, the bonding head 200 may define the second adsorption hole 290. The second adsorption hole 290 may penetrate the lower surface of the bonding head 200. The second adsorption hole 290 may be provided in the second electrode 210 and may penetrate the second insulating layer 230. The second electrode 210 may function as an adsorption unit. A lower portion of the second adsorption hole 290 may be open toward the bonding space 350. The second adsorption hole 290 may be connected to the second vacuum pump 280. In a bonding process, vacuum pressure may be applied to the second adsorption hole 290 by the second vacuum pump 280 so that the second adsorption hole 290 may be provided in a vacuum state. The bonding head 200 may be configured to fix and transfer a semiconductor chip by using the vacuum pressure in the second adsorption hole 290. The second vacuum pump 280 may be a separate configuration from the first vacuum pump 180. The second vacuum pump 280 may operate independently from the first vacuum pump 180. Accordingly, applying vacuum pressure to the second adsorption hole 290 may be independent of applying vacuum pressure to the first adsorption holes 190. The bonding head 200 may include a plurality of second adsorption holes 290.

The second vacuum pump 280 may be disposed on one side of the bonding head 200. Alternatively, the arrangement of the second vacuum pump 280 may be variously modified. For example, the second vacuum pump 280 may be provided on an upper surface of the bonding head 200.

The alternating current power generator 300 may electrically connect the first electrode 110 and the second electrode 210 to each other through wires 310. The alternating current power generator 300 may be configured to apply an alternating current voltage to the first electrode 110 and the second electrode 210. An alternating current electric field may be formed between the first electrode 110 and the second electrode 210 by applying the alternating current voltage to the first electrode 110 and the second electrode 210. For example, the alternating current electric field may be applied to the bonding space 350. The alternating current voltage may have a relatively high frequency. For example, the alternating current voltage may have a frequency of 100 kHz or more.

The wires 310 may be disposed between the first electrode 110 and the alternating current power generator 300 and between the second electrode 210 and the alternating current power generator 300. The wires 310 may each include a conductive material such as metal.

The apparatus 10 for manufacturing a semiconductor package may not include a heater. For example, a heater may not be provided in the bonding chuck 100 and the bonding head 200. The bonding chuck 100 and the bonding head 200 may not be connected to a heater.

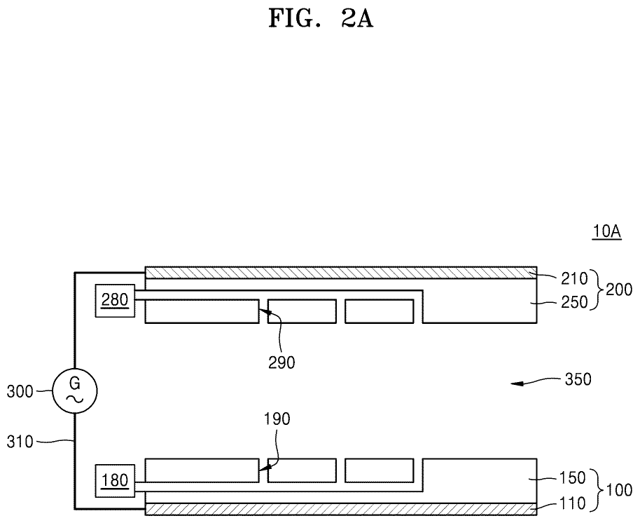

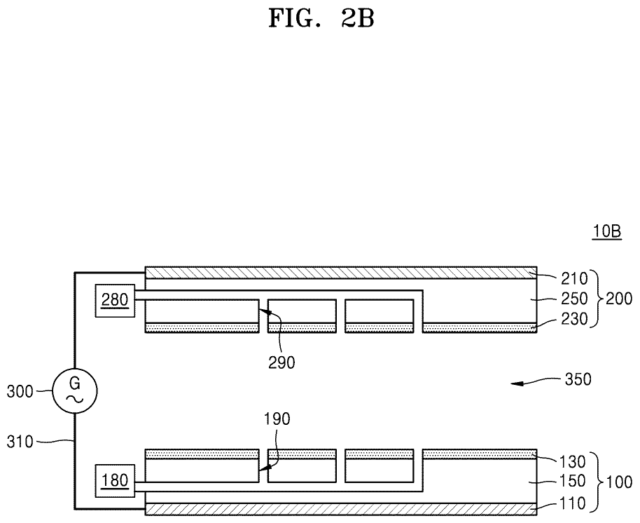

FIG. 2A is a diagram illustrating an apparatus for manufacturing a semiconductor package according to some example embodiments. Hereinafter, descriptions as those given above are omitted.

Referring to FIG. 2A, an apparatus 10A for manufacturing a semiconductor package may include the bonding chuck 100, the bonding head 200, and the alternating current power generator 300. The apparatus 10A for manufacturing a semiconductor package may further include the first vacuum pump 180 and the second vacuum pump 280.

The bonding chuck 100 may include the first electrode 110 and a first adsorption unit 150. The first adsorption unit 150 may be disposed on an upper surface of the first electrode 110. The first adsorption holes 190 may be provided in the first adsorption unit 150 and may penetrate an upper surface of the first adsorption unit 150. The upper surface of the first adsorption unit 150 may be an upper surface of the bonding chuck 100. The first adsorption unit 150 may include a material that is different from that of the first electrode 110. For example, the first adsorption unit 150 may include an insulating material. Accordingly, the first insulating layer 130 described with reference to FIG. 1 may be omitted.

The bonding head 200 may include the second electrode 210 and a second adsorption unit 250. The second adsorption unit 250 may be disposed on a lower surface of the second electrode 210. The second adsorption holes 290 may penetrate a lower surface of the second adsorption unit 250 and may be provided in the second adsorption unit 250. The lower surface of the second adsorption unit 250 may be a lower surface of the bonding head 200, but is not limited thereto. The second adsorption unit 250 may include a material that is different from that of the second electrode 210. For example, the second adsorption unit 250 may include an insulating material. Accordingly, the bonding head 200 may not include the second insulating layer 230 described with reference to FIG. 1.

FIG. 2B is a diagram illustrating an apparatus for manufacturing a semiconductor package according to some example embodiments.

Referring to FIG. 2B, an apparatus 10B for manufacturing a semiconductor package may include the bonding chuck 100, the bonding head 200, the alternating current power generator 300, the first vacuum pump 180, and the second vacuum pump 280.

The bonding chuck 100 may include the first electrode 110, the first adsorption unit 150, and the first insulating layer 130. The first adsorption unit 150 may be substantially the same as that described with reference to FIG. 2A. However, the first adsorption unit 150 may include a conductive material such as metal. The first insulating layer 130 may be further provided on an upper surface of the first adsorption unit 150. The first adsorption holes 190 may extend within the first insulating layer 130 to penetrate the first insulating layer 130.

The bonding head 200 may include the second electrode 210, the second adsorption unit 250, and the second insulating layer 230. The second adsorption unit 250 may be substantially the same as that described with reference to FIG. 2A. However, the second adsorption unit 250 may include a conductive material such as metal. The second insulating layer 230 may be further provided on a lower surface of the second adsorption unit 250. The second adsorption holes 290 may extend within the second insulating layer 230 to penetrate the second insulating layer 230.

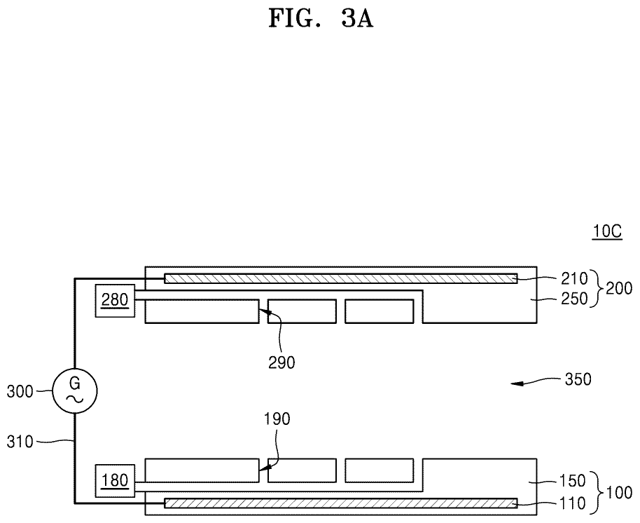

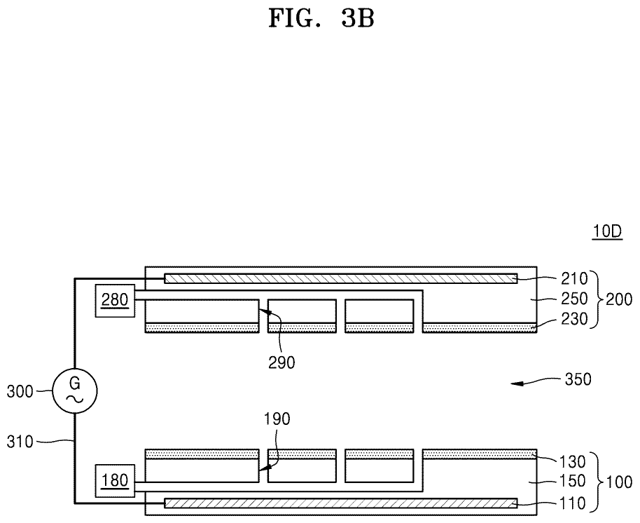

FIG. 3A is a diagram illustrating an apparatus for manufacturing a semiconductor package according to some example embodiments.

Referring to FIG. 3A, an apparatus 10C for manufacturing a semiconductor package may include the bonding chuck 100, the bonding head 200, and the alternating current power generator 300. The apparatus 10C for manufacturing a semiconductor package may further include the first vacuum pump 180 and the second vacuum pump 280.

The bonding chuck 100 may include the first electrode 110 and the first adsorption unit 150. The first electrode 110 may be provided within the first adsorption unit 150. For example, the first electrode 110 may be embedded in the first adsorption unit 150. The first adsorption unit 150 may include an insulating material.

The bonding head 200 may include the second electrode 210 and the second adsorption unit 250. The second electrode 210 may be provided within the second adsorption unit 250. For example, the second electrode 210 may be embedded in the second adsorption unit 250. The second adsorption unit 250 may include an insulating material.

FIG. 3B is a diagram illustrating an apparatus for manufacturing a semiconductor package according to an example embodiments.

Referring to FIG. 3B, an apparatus 10D for manufacturing a semiconductor package may include the bonding chuck 100, the bonding head 200, the alternating current power generator 300, the first vacuum pump 180, and the second vacuum pump 280.

The bonding chuck 100 may include the first electrode 110, the first adsorption unit 150, and the first insulating layer 130. The first electrode 110 may be provided within the first adsorption unit 150, as described above with reference to FIG. 3A. However, the first adsorption unit 150 may include a conductive material such as metal. The first insulating layer 130 may be further provided on an upper surface of the first adsorption unit 150. The first adsorption holes 190 may extend within the first insulating layer 130 to penetrate the first insulating layer 130.

The bonding head 200 may include the second electrode 210, the second adsorption unit 250, and the second insulating layer 230. The second electrode 210 may be provided within the second adsorption unit 250, as described above with reference to FIG. 3A. However, the second adsorption unit 250 may include a conductive material such as metal. The second insulating layer 230 may be further provided on a lower surface of the second adsorption unit 250. The second adsorption holes 290 may extend within the second insulating layer 230 to penetrate the second insulating layer 230.

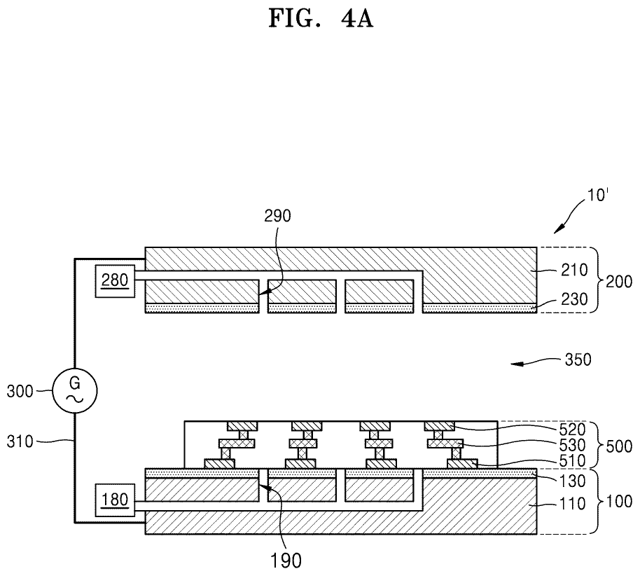

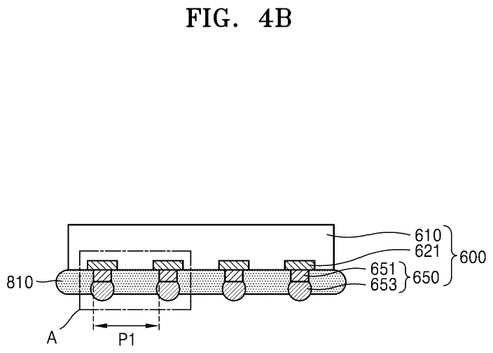

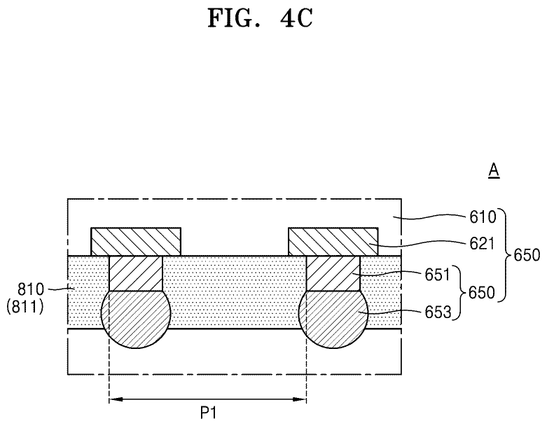

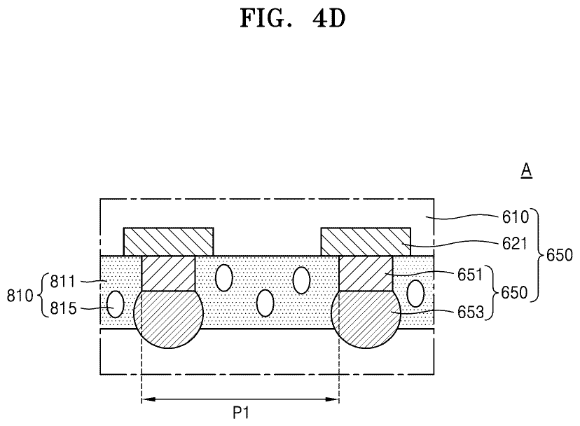

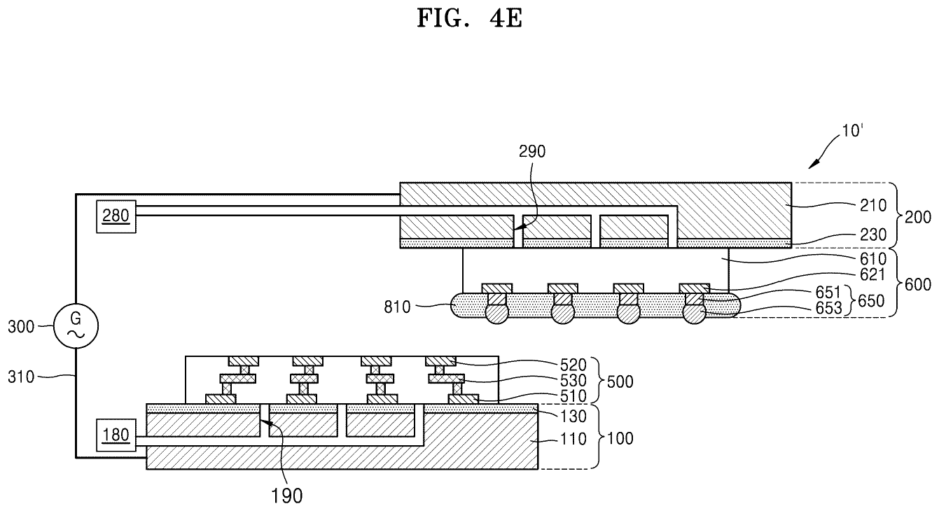

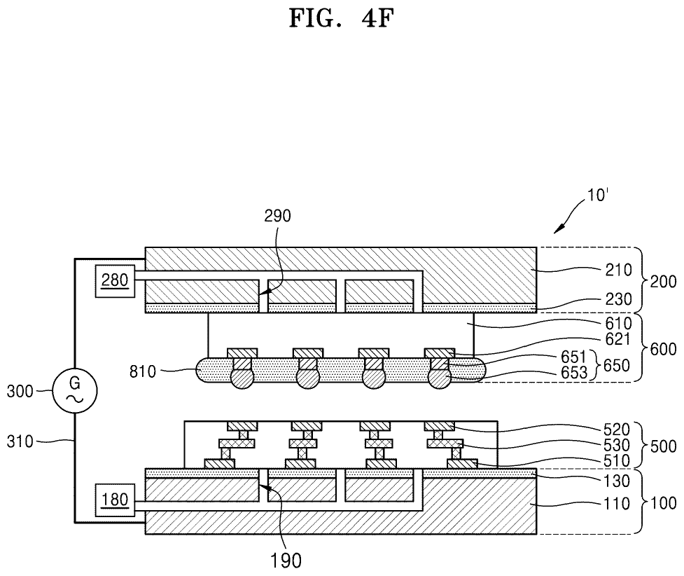

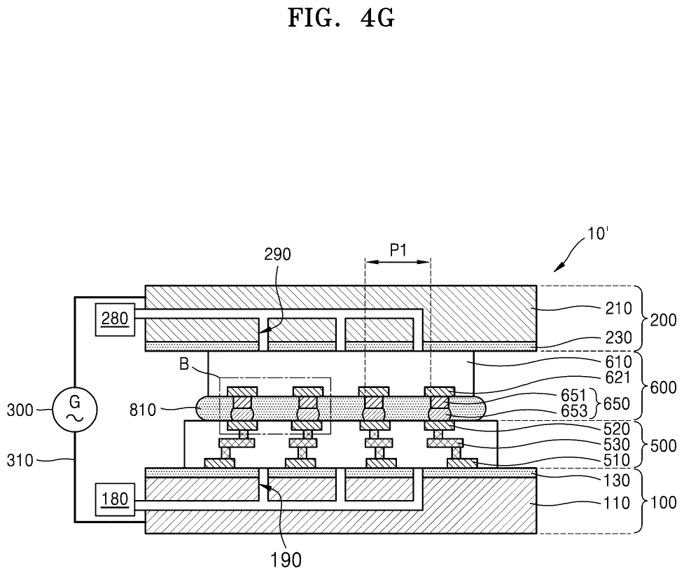

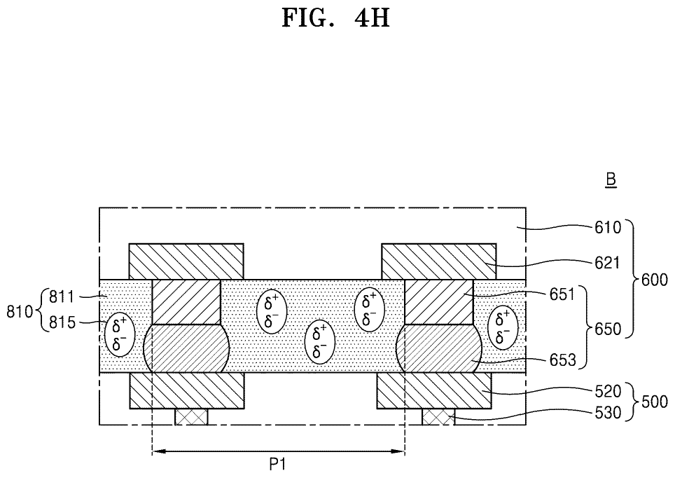

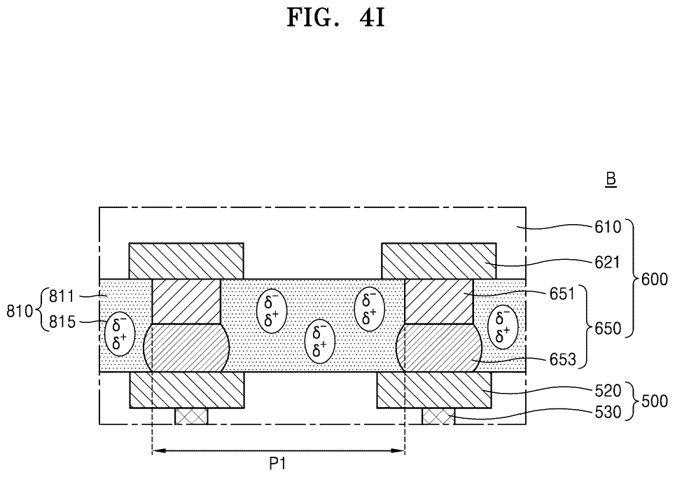

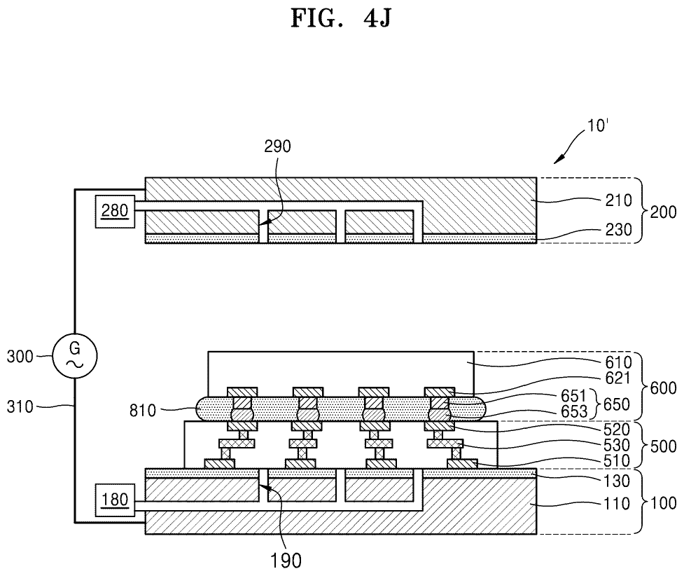

FIGS. 4A to 4J are diagrams illustrating a method of manufacturing a semiconductor package, according to some example embodiments. FIG. 4C is a diagram illustrating a first dielectric layer according to some example embodiments and is an enlarged view of a region A of FIG. 4B. FIG. 4D is a diagram illustrating a first dielectric layer according to some example embodiments, which corresponds to an enlarged view of the region A of FIG. 4B.

Referring to FIG. 4A, a bonding apparatus 10′ may be prepared. For example, the bonding apparatus 10′ may be the apparatus 10 for manufacturing a semiconductor package described in the example of FIG. 1. For example, the bonding apparatus 10′ may include the bonding chuck 100, the bonding head 200, and the alternating current power generator 300. The bonding apparatus 10′ may further include the first vacuum pump 180 and the second vacuum pump 280.

In contrast, the apparatus 10A for manufacturing a semiconductor package of FIG. 2A, the apparatus 10B for manufacturing a semiconductor package of FIG. 2B, the apparatus 10C for manufacturing a semiconductor package of FIG. 3A, or the apparatus 10D for manufacturing a semiconductor package of FIG. 3B may be used as the bonding apparatus 10′. For convenience, the apparatus 10 for manufacturing a semiconductor package of FIG. 1 is shown as being used as the bonding apparatus 10′, but the inventive concepts are not limited thereto.

A substrate 500 may be prepared. For example, the substrate 500 may include a printed circuit board or an interposer substrate. As another example, the substrate 500 may include a semiconductor substrate included in a lower semiconductor chip. In this case, providing the substrate 500 may include providing the lower semiconductor chip. The substrate 500 may include lower conductive pads 510, upper conductive pads 520, and conductive wires 530. The lower conductive pads 510 and the upper conductive pads 520 may respectively be disposed on lower and upper surfaces of the substrate 500. The conductive wires 530 may be provided in the substrate 500. The upper conductive pads 520 may be electrically connected to the lower conductive pads 510 through the conductive wires 530. The lower conductive pads 510, the upper conductive pads 520, and the conductive wires 530 may each include, for example, metal.

The substrate 500 may be loaded into the bonding apparatus 10′. For example, the substrate 500 may be provided on the upper surface of the bonding chuck 100. The width and length of the bonding chuck 100 may be equal to or greater than the width and length of the substrate 500, respectively. Accordingly, the bonding chuck 100 may stably support the substrate 500. The substrate 500 may overlap the first adsorption holes 190. The first vacuum pump 180 may operate to apply vacuum pressure to the first adsorption holes 190. An adsorption force may be applied to a lower surface of the substrate 500 by the vacuum pressure. Accordingly, the substrate 500 may be stably fixed to the bonding chuck 100.

Referring to FIG. 4B, a first semiconductor chip 600 may be prepared. The first semiconductor chip 600 may include a first semiconductor substrate 610, first integrated circuits (not shown), first lower pads 621, and first bumps 650. The first lower pads 621 may be provided on a lower surface of the first semiconductor substrate 610. The first semiconductor substrate 610 may include, for example, silicon, germanium, and/or a combination thereof. The first integrated circuits may be provided within the first semiconductor substrate 610 or on one surface of the first semiconductor substrate 610 and may be electrically connected to the first lower pads 621. The first lower pads 621 may include metal such as aluminum, copper, and/or nickel.

The first bumps 650 may be provided on a lower surface of the first semiconductor chip 600. For example, the first bumps 650 may be provided on lower surfaces of the first lower pads 621. The first bumps 650 may include first conductive pillars 651 and first solder balls 653. The first conductive pillars 651 may be provided on the lower surfaces of the first lower pads 621 to be connected to the first lower pads 621. Each of the first conductive pillars 651 may include, for example, a metal such as copper. The first solder balls 653 may be disposed on lower surfaces of the first conductive pillars 651. Each of the first solder balls 653 may include a solder material. For example, the first solder balls 653 may include tin (Sn), silver (Ag), zinc (Zn), and/or an alloy thereof. The first bumps 650 may have a first pitch P1. The first pitch P1 may be relatively small. For example, the first pitch P1 may be about 30 μm to about 150 μm. The first pitch P1 may correspond to a distance between the first conductive pillars 651.

Unlike the drawings, the first bumps 650 may include the first solder balls 653 but may not include the first conductive pillars 651. In this case, the first solder balls 653 may contact, for example directly contact, the lower surfaces of the first lower pads 621. The first pitch P1 may correspond to a distance between the first solder balls 653.

A first dielectric layer 810 may be provided on the lower surface of the first semiconductor chip 600. The first dielectric layer 810 may cover sidewalls of the first bumps 650 but may expose lower surfaces of the first bumps 650. The thickness of the first dielectric layer 810 may be less than the height of the first bumps 650. The lower surfaces of the first bumps 650 may correspond to lower surfaces of the first solder balls 653.

As shown in FIG. 4C, the first dielectric layer 810 may include a first base dielectric layer 811. The first base dielectric layer 811 may include, for example, an epoxy polymer or a non-conductive film (NCF).

As shown in FIG. 4D, the first dielectric layer 810 may further include first fillers 815, in addition to the first base dielectric layer 811. The first fillers 815 may be provided in the first base dielectric layer 811. The first fillers 815 may be dielectric fillers, which have dielectric characteristics. A dielectric constant of each of the first fillers 815 may be different from a dielectric constant of the first base dielectric layer 811. For example, the dielectric constant of each of the first fillers 815 may be greater than the dielectric constant of the first base dielectric layer 811. A dielectric constant of the first dielectric layer 810 may be adjusted by controlling a material type of the first fillers 815 and a content ratio of the first fillers 815. Each of the first fillers 815 may include a non-conductive material. The first fillers 815 may each include at least one of barium titanate (BaTiO₃), zinc oxide (ZnO), titanium oxide (TiO₂), and silicon oxide (SiO₂). The diameter of each of the first fillers 815 may be, for example, about 10 nm to about 10 m.

Referring to FIG. 4E, the bonding head 200 may move onto the first semiconductor chip 600. As the bonding head 200 descends toward the first semiconductor chip 600, the lower surface of the bonding head 200 may physically contact an upper surface of the first semiconductor chip 600. For example, the second insulating layer 230 may physically contact the upper surface of the first semiconductor chip 600. The second vacuum pump 280 may operate to apply vacuum pressure to the second adsorption holes 290. An adsorption force may be applied to the upper surface of the first semiconductor chip 600 by the vacuum pressure. The bonding head 200 that adsorbs the first semiconductor chip 600 may rise and horizontally move. Herein, “horizontally” may mean a direction parallel to the upper surface of the bonding chuck 100.

The width and length of the bonding head 200 may be equal to or greater than the width and length of the first semiconductor chip 600, respectively. Accordingly, the bonding head 200 may stably adsorb and move the first semiconductor chip 600.

For example, even when the bonding head 200 moves, the second vacuum pump 280 may not move. In this case, an adsorption path between the second vacuum pump 280 and the second adsorption holes 290 may be extended by the movement of the bonding head 200. Alternatively, the second vacuum pump 280 may move together with the bonding head 200.

Referring to FIG. 4F, the bonding head 200 may move to provide the first semiconductor chip 600 on the substrate 500. At this time, the first bumps 650 may vertically overlap the upper conductive pads 520. For example, the first bumps 650 may be vertically aligned with the upper conductive pads 520. Herein, “vertically” may mean a direction perpendicular to the upper surface of the bonding chuck 100. Being vertically aligned may mean alignment within an error range of a process.

Referring to FIG. 4G, the bonding head 200 descends so that the first semiconductor chip 600 may be in contact with the upper surface of the substrate 500. For example, the first bumps 650 may be provided on the upper conductive pads 520 to physically contact the upper conductive pads 520. The first bumps 650 may be bonded to the upper conductive pads 520 by performing a first bonding process. Bonding the first bumps 650 to the upper conductive pads 520 may mean bonding the first solder balls 653 to the upper conductive pads 520. The first bonding process may be a bonding process between the substrate 500 and the first semiconductor chip 600. The performing of the first bonding process may include applying an alternating current electric field to the first dielectric layer 810.

According to some example embodiments, the alternating current power generator 300 may operate to apply an alternating current voltage to the first electrode 110 and the second electrode 210. Accordingly, an alternating current electric field may be formed between the first electrode 110 and the second electrode 210. For example, the alternating current electric field may be applied to the first dielectric layer 810. Dielectric materials in the first dielectric layer 810 may form dipoles due to the alternating current electric field. Dielectric heating of the first dielectric layer 810 may occur due to the application of the alternating current electric field.

When the first dielectric layer 810 includes the first base dielectric layer 811, as shown in FIG. 4B, the dielectric materials may include dielectric materials in the first base dielectric layer 811. When the first dielectric layer 810 includes the first base dielectric layer 811 and the first fillers 815, as shown in FIG. 4C, the dielectric materials may include dielectric materials in the first base dielectric layer 811 and dielectric materials in the first fillers 815. Hereinafter, bonding formation between the first solder balls 653 and the upper conductive pads 520 by an alternating current electric field is described in more detail.

FIG. 4H is a diagram illustrating a dipole moment of a first dielectric layer in a first state according to the application of an alternating current electric field according to example embodiments, which corresponds to an enlarged view of a region B of FIG. 4G. FIG. 4I is a diagram illustrating a dipole moment of a first dielectric layer in a second state according to the application of an alternating current electric field, which corresponds to an enlarged view of the region B of FIG. 4G. Hereafter, for convenience of explanation, a case in which the first dielectric layer 810 includes the first base dielectric layer 811 and the first fillers 815 is shown in FIGS. 4H and 4I, but the description may also be applied to a case in which the first dielectric layer 810 does not include the first fillers 815.

Referring to FIGS. 4H and 4I together with FIG. 4G, the first dielectric layer 810 may form dipoles due to the application of an electric field. For example, each of the first base dielectric layer 811 and the first fillers 815 may form dipoles. Because the electric field is an alternating current electric field, a dipole moment of the first dielectric layer 810 may quickly change between a first state as shown in FIG. 4H and a second state as shown in FIG. 4I. Accordingly, the dipoles may quickly rotate and vibrate, and kinetic energy of the dipoles may be converted into heat energy. Accordingly, heat may be generated in the first dielectric layer 810. Heat of the first dielectric layer 810 may be transferred to the first solder balls 653. The first solder balls 653 may melt and reflow due to the heat. The first solder balls 653 may be bonded to the upper conductive pads 520 by the reflow of the first solder balls 653.

The alternating current voltage may have a relatively high frequency. Because the alternating current voltage has a frequency of 100 kHz or more, heat generated in the first dielectric layer 810 may be sufficient to reflow the first solder balls 653.

Referring to FIG. 4G again, the performing of the first bonding process may further include applying pressure on the first semiconductor chip 600 by using the bonding head 200. The first dielectric layer 810 may be in contact with the upper surface of the first semiconductor chip 600.

When heat generated from a heater of the bonding apparatus 10′ is transferred to the first bumps 650 through the substrate 500 and the first semiconductor chip 600, warpage of the substrate 500 or warpage of the semiconductor chip 600 may occur due to the heat. In addition, because heat is transferred to the first bumps 650 through the substrate 500 and the first semiconductor chip 600, the time of a bonding process may be increased.

According to some example embodiments, because the first dielectric layer 810 is locally heated by an alternating current electric field, the bonding apparatus 10′ may not include a heater. Accordingly, warpage of the substrate 500 and warpage of the first semiconductor chip 600 may be prevented or reduced in likelihood.

According to some example embodiments, because warpage of the substrate 500 and warpage of the first semiconductor chip 600 are prevented or reduced in likelihood, an electrical short between the first bumps 650 may be prevented or reduced in likelihood from occurring. Accordingly, the first bumps 650 may have a relatively small first pitch P1.

Because the first dielectric layer 810 is in physical contact, for example direct physical contact, with the sidewalls of the first bumps 650, heat generated in the first dielectric layer 810 may be transferred, for example directly transferred, to the first solder balls 653. Accordingly, the process time of the first bonding process may be reduced, and a process of manufacturing a semiconductor package may be performed more efficiently. For example, the first bonding process may be performed in 30 seconds or less. For example, applying an alternating current voltage to the first electrode 110 and the second electrode 210 may be performed in 30 seconds or less.

During the first bonding process, the substrate 500 and the first electrode 110 may be insulated from each other by the first insulating layer 130. For example, the lower conductive pads 510 may be electrically insulated from the first electrode 110 by the first insulating layer 130. The first semiconductor chip 600 may be electrically insulated from the second electrode 210 by the second insulating layer 230. An alternating current electric field may be formed at a desired intensity in a dielectric layer by the first insulating layer 130 and the second insulating layer 230.

Referring to FIG. 4J, when the first bonding process between the substrate 500 and the first semiconductor chip 600 is completed, the vacuum pressure in the second adsorption holes 290 may be removed, and the adsorption force applied to the first semiconductor chip 600 may be removed. The bonding head 200 may rise so that the bonding head 200 may be spaced apart from the first semiconductor chip 600.

According to some example embodiments, because bonding formation between the first solder balls 653 and the upper conductive pads 520 is performed by local heating of the first dielectric layer 810, the substrate 500, the first semiconductor chip 600, the bonding chuck 100, and the bonding head 200 may each have a relatively low temperature after the completion of the first bonding process. Accordingly, after the completion of the first bonding process, a cooling process of the bonding chuck 100, the bonding head 200, the substrate 500, or the first semiconductor chip 600 may be omitted, or the cooling process time of the bonding chuck 100, the bonding head 200, the substrate 500, or the first semiconductor chip 600 may be significantly reduced. Accordingly, efficiency and productivity of a process of manufacturing a semiconductor package may be improved.

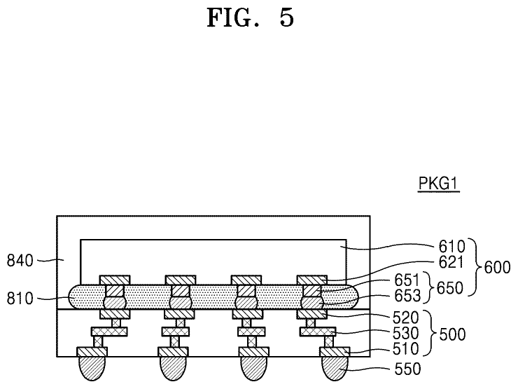

FIG. 5 is a cross-sectional view of a semiconductor package according to some example embodiments.

Referring to FIG. 5, a semiconductor package PKG1 may include the substrate 500, the first semiconductor chip 600, the first dielectric layer 810, solder ball terminals 550, and a molding layer 840. The first semiconductor chip 600 may be mounted on the substrate 500. The first dielectric layer 810 may be disposed between the substrate 500 and the first semiconductor chip 600 to cover the sidewalls of the first bumps 650. The first bonding process between the substrate 500 and the first semiconductor chip 600 may be performed by the methods described in the examples with reference to FIGS. 4A to 4J. After the bonding head 200 is spaced apart from the first semiconductor chip 600 as described in the example with reference to FIG. 4J, the substrate 500 and the first semiconductor chip 600 may be unloaded from the bonding apparatus 10′. The solder ball terminals 550 may be disposed on the lower surface of the substrate 500, which is unloaded from the bonding apparatus 10′, to be connected to the lower conductive pads 510. Each of the solder ball terminals 550 may include a solder material.

The molding layer 840 may be disposed on the upper surface of the substrate 500 to cover the first semiconductor chip 600. The molding layer 840 may further cover sidewalls of the first dielectric layer 810. The molding layer 840 may include an insulating polymer such as an epoxy-based molding compound (EMC).

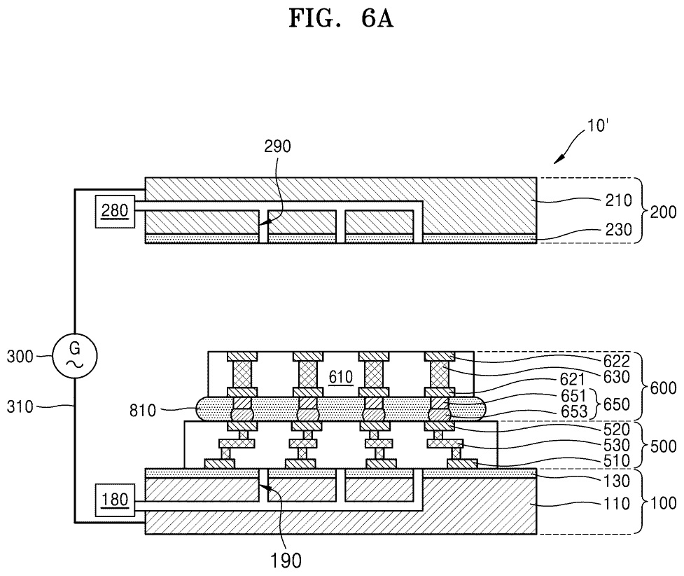

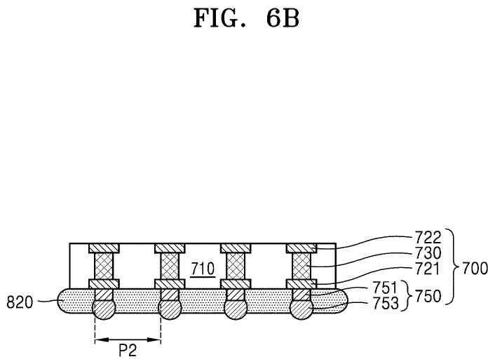

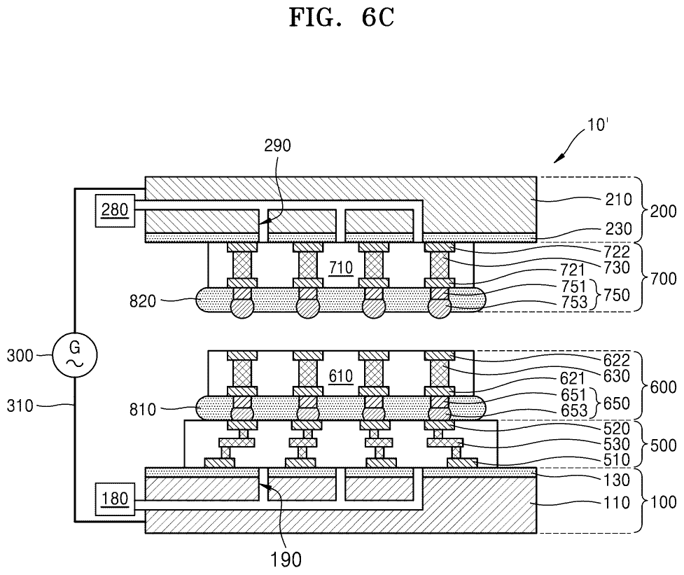

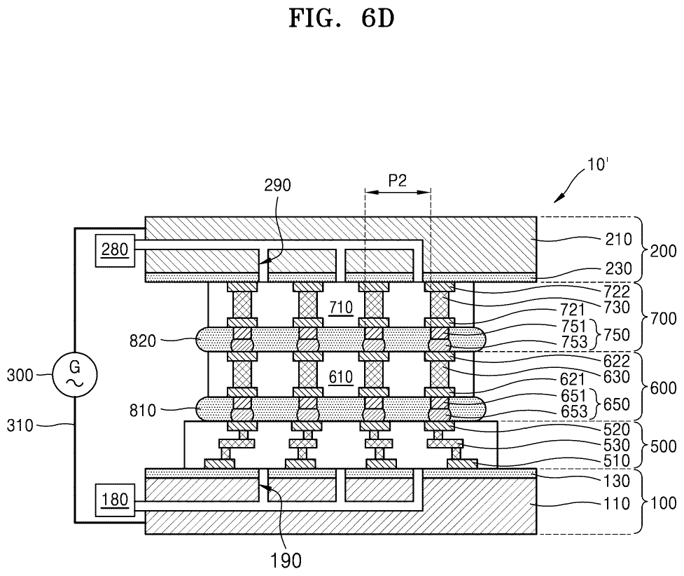

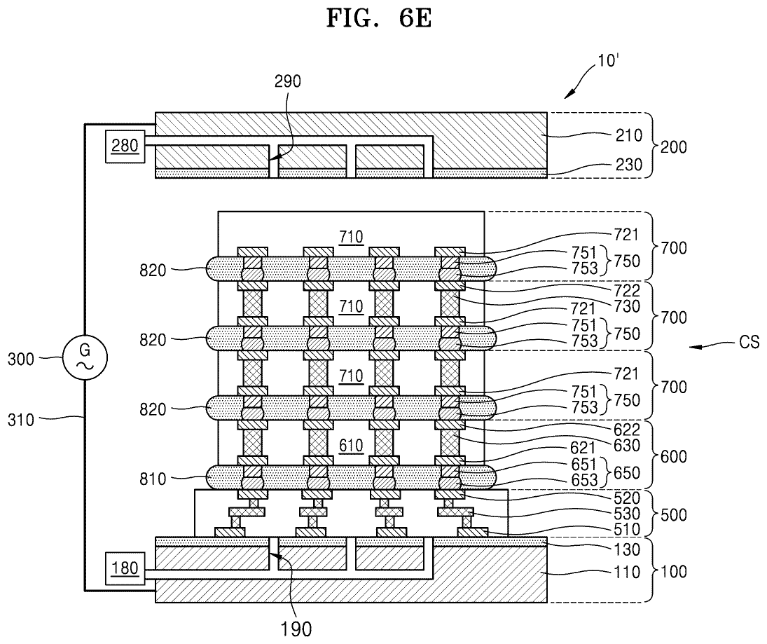

FIGS. 6A to 6E are diagrams illustrating a method of manufacturing a semiconductor package, according to some example embodiments.

Referring to FIG. 6A, the bonding apparatus 10′ may be prepared. For example, the bonding apparatus 10′ may be the apparatus 10 for manufacturing a semiconductor package described in the example with reference to FIG. 1. Unlike the drawings, the apparatus 10A for manufacturing a semiconductor package of FIG. 2A, the apparatus 10B for manufacturing a semiconductor package of FIG. 2B, the apparatus 10C for manufacturing a semiconductor package of FIG. 3A, or the apparatus 10D for manufacturing a semiconductor package of FIG. 3B may be used as the bonding apparatus 10′.

The substrate 500 and the first semiconductor chip 600, which are bonded to each other, may be prepared. Bonding between the substrate 500 and the first semiconductor chip 600 may be formed by the method described in the examples with reference to FIGS. 4A to 4J. The substrate 500 may include substantially the same as that described in the examples with reference to FIG. 4A. For example, the substrate 500 may be a printed circuit board, an interposer substrate, or a semiconductor substrate included in a lower semiconductor chip. As another example, the substrate 500 may be a temporary substrate such as a carrier substrate.

Unlike the above description, the first semiconductor chip 600 may further include first through vias 630 and first upper pads 622, in addition to the first semiconductor substrate 610, the first lower pads 621, and the first bumps 650. The first upper pads 622 may be disposed on the upper surface of the first semiconductor chip 600. For example, the first upper pads 622 may be formed on the upper surface of the first semiconductor substrate 610. The first through vias 630 may be provided within the first semiconductor substrate 610 and may be electrically connected to the first upper pads 622 and the first lower pads 621. The first upper pads 622 may be electrically connected to first integrated circuits (not shown) and the first lower pads 621 through the first through vias 630. The first upper pads 622 and the first through vias 630 may each include metal such as copper, tungsten, aluminum, and/or titanium.

Referring to FIG. 6B, a second semiconductor chip 700 may be prepared. The second semiconductor chip 700 may include a second semiconductor substrate 710, second integrated circuits (not shown), second lower pads 721, second bumps 750, second through vias 730, and second upper pads 722. Arrangement relationships and materials of the second semiconductor substrate 710, the second integrated circuits (not shown), the second lower pads 721, and the second bumps 750 may be the same as or similar to those of the first semiconductor substrate 610, the first integrated circuits (not shown), the first lower pads 621, and the first bumps 650 described above with reference to FIG. 4B. An arrangement and materials of the second through vias 730 and the second upper pads 722 may be the same as or similar to those of the first through vias 630 and the first upper pads 622 described above with reference to FIG. 5A.

For example, the second lower pads 721 may be provided on lower surface of the second semiconductor substrate 710, and the second upper pads 722 may be provided upper surface of the second semiconductor substrate 710. The second lower pads 721 and the second upper pads 722 may be electrically connected to the second integrated circuits. The second through vias 730 may be provided within the second semiconductor substrate 710 and may be electrically connected to the second upper pads 722 and the second lower pads 721.

The second bumps 750 may be provided on a lower surface of the second semiconductor chip 700. The second bumps 750 may include second conductive pillars 751 and second solder balls 753. The second conductive pillars 751 may be provided on lower surfaces of the second lower pads 721 to be connected to the second lower pads 721. Each of the second conductive pillars 751 may include, for example, a metal such as copper. The second solder balls 753 may be disposed on lower surfaces of the second conductive pillars 751. Each of the second solder balls 753 may include a solder material. The second bumps 750 may have a second pitch P2. The second pitch P2 may be relatively small. For example, the second pitch P2 may be about 30 μm to about 150 μm. The second pitch P2 may correspond to a distance between the second conductive pillars 751.

Unlike the drawings, the second bumps 750 may include the second solder balls 753 but may not include the second conductive pillars 751. In this case, the second solder balls 753 may contact, for example directly contact, the lower surfaces of the second lower pads 721. The second pitch P2 may correspond to a distance between the second solder balls 753.

A second dielectric layer 820 may be provided on the lower surface of the second semiconductor chip 700. The second dielectric layer 820 may cover sidewalls of the second bumps 750 but may expose lower surfaces of the second bumps 750. The thickness of the second dielectric layer 820 may be less than the height of the second bumps 750. The lower surfaces of the second bumps 750 may correspond to lower surfaces of the second solder balls 753.

The second dielectric layer 820 may include a second base dielectric layer. The second base dielectric layer may include, for example, an epoxy polymer or an NCF. As another example, the second dielectric layer 820 may include second fillers, in addition to the second base dielectric layer. The second fillers may be provided within the second base dielectric layer. The second fillers may include the material as described in the example of the first fillers 815 with reference to FIG. 4D. A dielectric constant of each of the second fillers may be greater than a dielectric constant of the second base dielectric layer. A dielectric constant of the second dielectric layer 820 may be adjusted by the second fillers. The diameter of each of the second fillers may be, for example, about 10 nm to about 10 μm.

Referring to FIG. 6C, the second semiconductor chip 700 may be provided on the first semiconductor chip 600 by the bonding head 200. At this time, the second bumps 750 may be vertically aligned with the first upper pads 622.

First, the bonding head 200 may move onto the second semiconductor chip 700 of FIG. 6B. The bonding head 200 may descend so that the lower surface of the bonding head 200 may physically contact an upper surface of the second semiconductor chip 700. The second vacuum pump 280 may operate to apply vacuum pressure to the second adsorption holes 290. The bonding head 200 may adsorb the upper surface of the second semiconductor chip 700 by the vacuum pressure. Thereafter, the bonding head 200 may rise and move horizontally together with the second semiconductor chip 700.

Referring to FIG. 6D, the bonding head 200 may descend to stack the second semiconductor chip 700 on the first semiconductor chip 600. The lower surfaces of the second bumps 750 may be provided on the first upper pads 622 and may physically contact the first upper pads 622. The second bumps 750 may be bonded to the second upper pads 722 by performing a second bonding process. The second bonding process may be a bonding process between the first semiconductor chip 600 and the second semiconductor chip 700. The performing of the second bonding process may include applying an alternating current electric field to the second dielectric layer 820. For example, the alternating current power generator 300 may operate to apply an alternating current voltage to the first electrode 110 and the second electrode 210. Accordingly, an alternating current electric field may be formed between the first electrode 110 and the second electrode 210, and the alternating current electric field may be applied to the first dielectric layer 810. Dielectric materials in the second dielectric layer 820 may form dipoles due to the alternating current electric field. Dielectric heating of the second dielectric layer 820 may occur due to the application of the alternating current electric field. For example, the dipoles may vibrate, and heat may be generated in the second dielectric layer 820. Because the second dielectric layer 820 is in direct physical contact with the sidewalls of the second bumps 750, heat generated in the second dielectric layer 820 may be quickly transferred to the second solder balls 753. The second solder balls 753 may reflow due to the heat to be connected to the second upper pads 722. Accordingly, the process time of the second bonding process may be reduced, and a process of manufacturing a semiconductor package may be performed more efficiently. Bonding the second bumps 750 to the second upper pads 722 may mean bonding the second solder balls 753 to the second upper pads 722.

According to some example embodiments, an alternating current voltage has a frequency of 100 kHz or more, heat generated in the second dielectric layer 820 may be sufficient to reflow the second solder balls 753.

According to some example embodiments, because the second dielectric layer 820 is locally heated due to an alternating current electric field without a separate heating process, warpage of the first semiconductor chip 600 and warpage of the second semiconductor chip 700 may be prevented or reduced in likelihood. The bonding apparatus 10′ may not include a heater. Because warpage of the first semiconductor chip 600 and warpage of the second semiconductor chip 700 are prevented or reduced in likelihood, an electrical short between the second bumps 750 may be prevented or reduced in likelihood. Accordingly, the second bumps 750 may have a relatively small second pitch P2.

During the second bonding process, the second semiconductor chip 700 may be electrically insulated from the second electrode 210 by the second insulating layer 230. For example, the second upper pads 722 may be electrically insulated from the second electrode 210 by the second insulating layer 230.

Referring to FIG. 6E, a chip stack CS may be manufactured by repeatedly performing stacking of the second semiconductor chip 700 and the second bonding process by using the bonding apparatus 10′. The stacking of the second semiconductor chip 700 and the second bonding process may be performed by substantially the same methods as described in the examples with reference to FIGS. 6A to 6D. Accordingly, a plurality of second semiconductor chips 700 may be stacked on the first semiconductor chip 600. The chip stack CS may include the first semiconductor chip 600, the first dielectric layer 810, the plurality of second semiconductor chips 700, which are stacked, and the second dielectric layer 820. Adjacent second semiconductor chips 700 may be bonded to each other. For example, the adjacent second semiconductor chips 700 may include a second lower semiconductor chip and a second upper semiconductor chip. The second bumps 750 of the upper semiconductor chip may be bonded to the second upper pads 722 of the second lower semiconductor chip. Accordingly, the second upper semiconductor chip may be electrically connected to the second lower semiconductor chip. The second dielectric layer 820 may be disposed between the second lower semiconductor chip and the second upper semiconductor chip to cover the sidewalls of the second bumps 750. The chip stack CS may include a plurality of second dielectric layers 820, and the second dielectric layers 820 may be respectively provided between the second semiconductor chips 700.

An uppermost second semiconductor chip 700 may not include the second through vias 730 and the second upper pads 722. The uppermost second semiconductor chip 700 may have a greater thickness than that of other second semiconductor chips 700. The number of second semiconductor chips 700 stacked is not limited to that shown in FIG. 6E and may be variously modified.

When a second bonding process of the upper most second semiconductor chip 700 is completed, the vacuum pressure in the second adsorption holes 290 may be removed, and the adsorption force applied to the second semiconductor chip 700 may be removed. The bonding head 200 may rise so that the bonding head 200 may be spaced apart from the second semiconductor chip 700.

Thereafter, the substrate 500 and the chip stack CS may be unloaded from the bonding apparatus 10′.

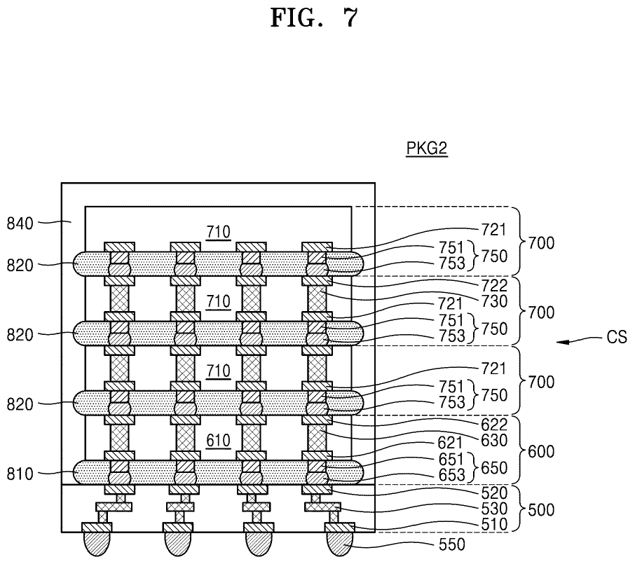

FIG. 7 is a cross-sectional view of a semiconductor package according to embodiments.

Referring to FIG. 7, a semiconductor package PKG2 may include the substrate 500, the chip stack CS, the solder ball terminals 550, and the molding layer 840. The first semiconductor chip 600 may be mounted on the substrate 500. The chip stack CS may be manufactured by the method described in the examples with reference to FIGS. 6A to 6E. The first bonding process between the substrate 500 and the first semiconductor chip 600 may be performed by the methods described in the examples with reference to FIGS. 4A to 4J.

The molding layer 840 may be disposed on the upper surface of the substrate 500 to cover sidewalls of the first semiconductor chip 600 and sidewalls of the second semiconductor chip 700. The molding layer 840 may further cover sidewalls of the first dielectric layer 810 and sidewalls of the second dielectric layers 820.

Example embodiments of the inventive concepts may be combined with each other.

According to some example embodiments, an alternating current electric field may be applied a dielectric layer so that heat may be generated in the dielectric layer due to dielectric heating. Because the dielectric layer may physically contact sidewalls of solder balls, heat generated in the dielectric layer may be quickly transferred to the solder balls. The solder balls may reflow due to the heat to be bonded to upper pads. Accordingly, the process time of a bonding process may be reduced, and productivity of a process of manufacturing a semiconductor package may be improved. Warpage of a semiconductor chip or a substrate may be prevented or reduced in likelihood, and bumps may have a small pitch.

While the inventive concepts have been particularly shown and described with reference to example embodiments thereof, it will be understood that various changes in form and details may be made therein without departing from the spirit and scope of the following claims.

What is claimed is:

1. A method of manufacturing a semiconductor package, the method comprising:
preparing a substrate including upper conductive pads on an upper surface of the substrate;
preparing a first semiconductor chip including first solder balls, the first semiconductor chip including a first dielectric layer covering sidewalls of the first solder balls on a lower surface of the first semiconductor chip;
disposing the first semiconductor chip on the substrate such that the first solder balls are on the upper conductive pads; and
bonding the first solder balls to the upper conductive pads by applying an alternating current electric field to the first dielectric layer.

2. The method of claim 1, wherein the applying of the alternating current electric field comprises:
generating heat in the first dielectric layer,
wherein the first solder balls reflow in response to the heat.

3. The method of claim 1, wherein the first dielectric layer comprises:
a base dielectric layer; and
fillers within the base dielectric layer,
wherein a dielectric constant of each of the fillers is greater than a dielectric constant of the base dielectric layer.

4. The method of claim 3, wherein
the base dielectric layer includes an epoxy polymer or a non-conductive film (NCF), and
each of the fillers includes at least one of barium titanate (BaTiO₃), zinc oxide (ZnO), titanium oxide (TiO₂), or silicon oxide (SiO₂).

5. The method of claim 1, further comprising:
preparing a second semiconductor chip including second solder balls, wherein a second dielectric layer covering sidewalls of the second solder balls is provided on a lower surface of the second semiconductor chip;
disposing the second semiconductor chip on the first semiconductor chip so that the second solder balls are aligned with first upper conductive pads of the first semiconductor chip; and
bonding the second solder balls to the first upper conductive pads by applying an alternating current electric field to the second dielectric layer,
wherein the first upper conductive pads are disposed on an upper surface of the first semiconductor chip.

6. The method of claim 1, wherein an operation of heating the substrate and the first semiconductor chip by using a heater is not performed while bonding the first solder balls to the upper conductive pads.

7. The method of claim 1, further comprising:
applying pressure on the first semiconductor chip while applying the alternating current electric field to the first dielectric layer.

8. The method of claim 1, wherein the substrate comprises:
a semiconductor substrate of a lower semiconductor chip.

9. An apparatus for manufacturing a semiconductor package, the apparatus comprising:
a bonding chuck including a first electrode and defining a first adsorption hole;
a bonding head including a second electrode and defining a second adsorption hole; and
an alternating current power generator electrically connected to the first electrode and the second electrode, wherein
the apparatus is configured to apply an alternating current voltage to the first electrode and the second electrode by driving the alternating current power generator,
the first adsorption hole penetrates an upper surface of the bonding chuck, and
the second adsorption hole penetrates a lower surface of the bonding head.

10. The apparatus of claim 9, wherein
the bonding chuck is configured to fix a substrate, and the substrate includes upper conductive pads on an upper surface of the substrate,
the bonding head is configured to move a semiconductor chip onto the substrate, and the semiconductor chip includes solder balls on a lower surface of the semiconductor chip,
a dielectric layer is on the lower surface of the semiconductor chip, the dielectric layer covering the solder balls,
the apparatus is configured to reflow the solder balls in response to heat from the dielectric layer, wherein the heat is generated in the dielectric layer by applying the alternating current voltage.

11. The apparatus of claim 9, wherein the bonding chuck further comprises:
a first insulating layer on an upper surface of the first electrode, and
the bonding head further includes a second insulating layer on a lower surface of the second electrode.

12. The apparatus of claim 11, wherein
the first adsorption hole extends into the first electrode by penetrating the first insulating layer, and
the second adsorption hole extends into the second electrode by penetrating the second insulating layer.

13. The apparatus of claim 9, wherein the alternating current power generator is configured to apply the alternating current voltage having a frequency of 100 kHz or more to the first electrode and the second electrode.

14. The apparatus of claim 9, wherein the bonding chuck further comprises:
a first adsorption unit with the first adsorption hole,
the first electrode is embedded in the first adsorption unit,
the bonding head further includes a second adsorption unit with the second adsorption hole, and
the second electrode is embedded in the second adsorption unit.

15. The apparatus of claim 9, further comprising:
a first vacuum pump configured to apply vacuum pressure to the first adsorption hole; and
a second vacuum pump configured to apply vacuum pressure to the second adsorption hole.

16. A method of manufacturing a semiconductor package, the method comprising:
preparing a bonding apparatus including
a bonding chuck, the bonding chuck including a first electrode,
a bonding head, the bonding head including a second electrode, and
an alternating current power generator electrically connecting the first electrode to the second electrode;
disposing a substrate on the bonding chuck, the substrate including upper conductive pads;
preparing a semiconductor chip including solder balls, the semiconductor chip including a dielectric layer covering sidewalls of the solder balls and exposing lower surfaces of the solder balls, and the dielectric layer on a lower surface of the semiconductor chip;
disposing the semiconductor chip on the substrate by using the bonding head such that the solder balls are provided on the upper conductive pads; and
bonding the solder balls to the upper conductive pads by applying an alternating current voltage to the first electrode and the second electrode.

17. The method of claim 16, wherein
the applying of the alternating current voltage includes generating heat from the dielectric layer by applying an alternating current electric field to the dielectric layer, and
the solder balls reflow in response to the heat.

18. The method of claim 16, wherein the dielectric layer comprises:
a base dielectric layer; and
dielectric fillers within the base dielectric layer,
wherein a dielectric constant of each of the dielectric fillers is different from a dielectric constant of the base dielectric layer.

19. The method of claim 16, wherein the bonding chuck further comprises:
a first insulating layer on an upper surface of the first electrode,
the bonding head further includes a second insulating layer on a lower surface of the second electrode,
the substrate is spaced apart from the first electrode by the first insulating layer, and
the semiconductor chip is spaced apart from the second electrode by the second insulating layer.

20. The method of claim 16, wherein
the bonding chuck defines a first adsorption hole penetrating an upper surface of the bonding chuck, and
the bonding head defines a second adsorption hole penetrating a lower surface of the bonding head.
